(19) United States
(12) Patent Application Publication
(10) Pub. No.: US 2007/0221129 A1
(43) Pub. Date: Sep. 27, 2007

(54) APPARATUS FOR DEPOSITING ATOMIC LAYER USING GAS SEPARATION TYPE SHOWERHEAD

(75) Inventors: Guen Hag Bae, Kyungki-do (KR); Kyung Soo Kim, Seoul (KR); Ho Sik Kim, Kyungki-do (KR)

Correspondence Address: CANTOR COLBURN, LLP, 55 GRIFFIN ROAD SOUTH, BLOOMFIELD, CT, 06002, US

(73) Assignee: ATTO CO., LTD, Kyungki-do (KR)

(21) Appl. No.: 11/684,367

(22) Filed: Mar. 9, 2007

(30) Foreign Application Priority Data
Mar. 21, 2006 (KR) 10-2006-0025775
Apr. 14, 2006 (KR) 10-2006-0034183

(51) Int. Cl. C23C 16/00

(52) U.S. Cl. 118/715

(57) ABSTRACT

An atomic layer deposition (ALD) apparatus using a gas separation type showerhead is provided. Accordingly, the ALD apparatus that employs the gas separation type showerhead including a gas supply module, a gas separation module, and a gas injection module. The ALD apparatus includes: a first precursor source storing the first precursor, which is connected to the outer supply tube; a second precursor source storing the second precursor, which is connected to the inner supply tube; a purge gas source storing a purge gas, which is connected to the outer and inner supply tubes; a power source which applies power for ionization to the gas separation module; and an exhaust unit which exhausts remaining materials of the reaction chamber.

### BACKGROUND OF THE INVENTION

1. Field of the Invention

The present invention relates to an atomic layer deposition (ALD) process, and more particularly, to an ALD apparatus using a gas separation type showerhead.

2. Description of the Related Art

An ALD process is used for a process of depositing a semiconductor thin film with a thickness less than 90 nm so as to form the thin film with a uniform thickness while suppressing impurities to the highest degree. In a general ALD process, a cycle in which a precursor is adsorbed and purged out and another precursor is adsorbed and purged out is repeated.

However, in the conventional ALD apparatus, since the precursors are finally injected through different injection holes, consistency in process conditions is disturbed due to a change of a gas flow. A reaction time increases.

On the other hand, since reactivity between a reaction gas and a deposition gas has to be large at a relatively low processing temperature for the ALD process, available kinds of precursors are less than those of precursors in a CVD process. In order to solve the aforementioned problem, a method of depositing a semiconductor thin film by improving reactivity of the reaction gas through a plasma enhanced ALD (PE-ALD), in which plasma is applied into the reaction chamber, is used.

In the PE-ALD process, when the plasma is applied into the reaction chamber, a semiconductor element or substrate may be damaged due to the direct influence of the plasma. In order to minimize the damage due to the plasma, remote plasma, which is previously formed out of the reaction chamber, is generally used. However, in this case, the plasma efficiency is reduced due to recombination of ions while the ionized precursors are being supplied to the reaction chamber through a supply line.

### SUMMARY OF THE INVENTION

The present invention provides an ALD apparatus using a gas separation type showerhead capable of suppressing production of by-products in a showerhead and maintaining uniformity of a gas flow in a reaction chamber by using the showerhead in which precursors can be separately supplied and finally injected through the same injection holes.

The present invention also provides an ALD apparatus using a gas separation type showerhead capable of improving plasma efficiency by directly applying power for ionization to a gas separation module of the gas separation type showerhead and minimizing an influence of generation of plasma on a semiconductor substrate.

According to an aspect of the present invention, there is provided an atomic layer deposition (ALD) apparatus that employs a gas separation type showerhead which includes a gas supply module having an outer supply tube through which a first precursor is supplied and an inner supply tube through which a second precursor is supplied, a gas separation module having a first dispersion region connected to the outer supply tube and a second dispersion region connected to the inner supply tube, and a gas injection module having a plurality of common holes through which the first and second precursors are alternately injected into a reaction chamber, the ALD apparatus comprising a first precursor source, a second precursor source, a purge gas source, a power source, and an exhaust unit.

The first precursor source storing the first precursor may be connected to the outer supply tube. The second precursor source storing the second precursor may be connected to the inner supply tube. The purge gas source storing a purge gas may be connected to the outer and inner supply tubes. The power source may apply power for ionization to the gas separation module. The exhaust unit may exhaust remaining materials of the reaction chamber.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates an example of a gas separation type showerhead used for the present invention;

FIG. 2 illustrates a part of a gas separation module and a part of a gas injection module of the gas separation type showerhead shown in FIG. 1, in detail;

FIG. 3 illustrates an ALD apparatus according to an embodiment of the present invention;

FIG. 4 illustrates an ALD apparatus according to another embodiment of the present invention; and

FIGS. 5 to 9 illustrate examples of a gas separation type showerhead used for the present invention.

### DETAILED DESCRIPTION OF THE INVENTION

Now, preferred embodiments of the present invention will be described in detail with reference to the attached drawings.

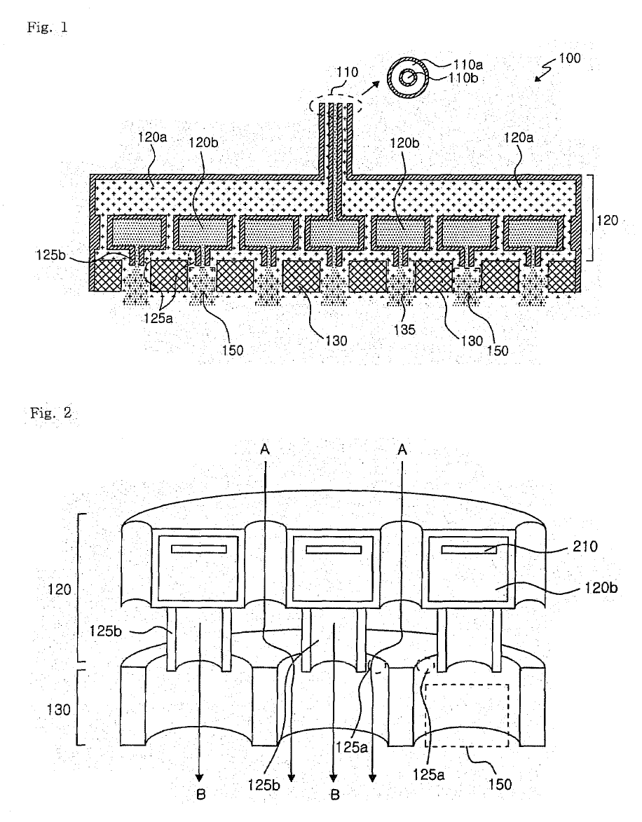

FIG. 1 illustrates a gas separation type showerhead used for the present invention. A gas separation type showerhead 100 shown in FIG. 1 includes a gas supply module 110, a gas separation module 120, and a gas injection module 130.

The gas supply module 110 includes outer and inner supply tubes 110a and 110b which are separated from each other. A first precursor A is supplied to the outer supply tube 110a, and a second precursor B is supplied to the inner supply tube 110b.

The gas separation module 120 includes a first dispersion region 120a connected to the outer supply tube 110a and a second dispersion region 120b connected to the inner supply tube 110b. Referring to FIG. 1, the first precursor A is supplied to the outer supply tube 110a and dispersed in the first dispersion region 120a. The second precursor B is supplied to the inner supply tube 110b and dispersed in the second dispersion region 120b.

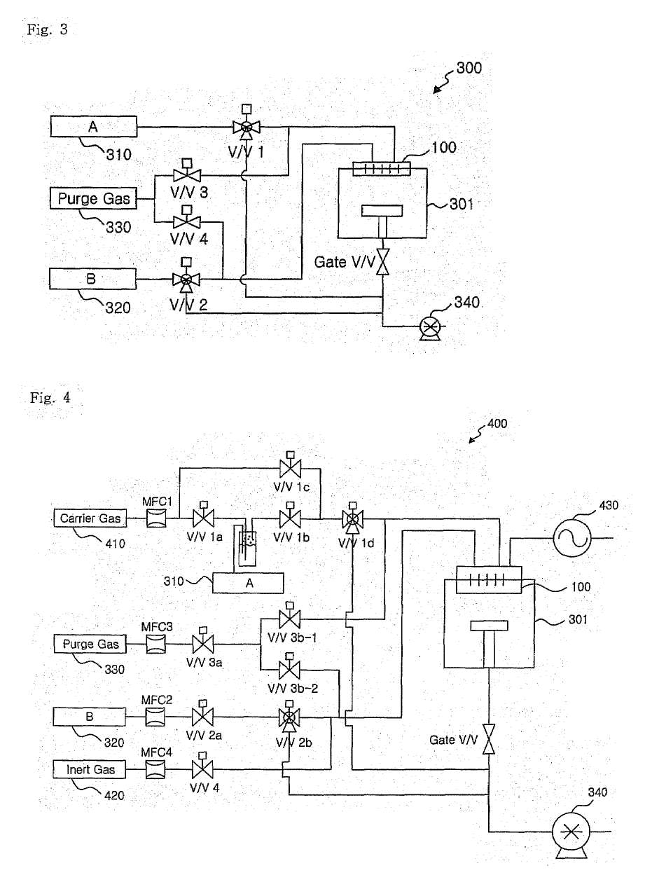

The first dispersion region 120a is constructed with one region. The second dispersion region 120b is located under the first dispersion region 120a and divided into a plurality of regions. A gas distribution plate 210 (FIG. 2) may be provided so as to uniformly disperse the second precursor B in the divided regions of the second dispersion region 120b.

Neighboring divided regions of the second dispersion region 120b are spaced apart from each other, that is, a constant space exists between the outer surfaces of the neighboring divided regions. Further, a vent 125b is located at the lower part of each region of the second dispersion region 120b.

FIG. 2 illustrates a part of a gas separation module and a part of a gas injection module of the gas separation type showerhead shown in FIG. 1, in detail.

Referring to FIG. 2, the second precursor B is vented to the gas injection module 130 through the plurality of vents 125b. The first precursor A is vented to the gas injection module 130 from the first dispersion region 120a through the outer spaces of the second dispersion region 120b and spaces 125a surrounding the vents 125b.

Locations 150 in a reaction chamber, into which the first and second precursors A and B are injected, are determined depending on heights of ends of the vents 125b. The vents 125b may be located higher than the top of the gas injection module 130, according to objects of processing. Alternatively, the vents 125b may be located between the top and the bottom of the gas injection module 130.

The gas injection module 130 includes a plurality of common holes 135. The first and second precursors A and B are injected into the reaction chamber through the plurality of common holes 135.

In order to use the gas separation type showerhead 100 for an atomic layer deposition (ALD) process, the first and second precursors A and B are alternately injected. That is, when the first precursor A is injected into the reaction chamber, only the first precursor A is supplied to the outer supply tube 110a, and the second precursor B is not supplied to the inner supply tube 110b. Alternatively, when the second precursor B is injected into the reaction chamber, only the second precursor B is supplied to the inner supply tube 110b, and the first precursor A is not supplied to the outer supply tube 110a.

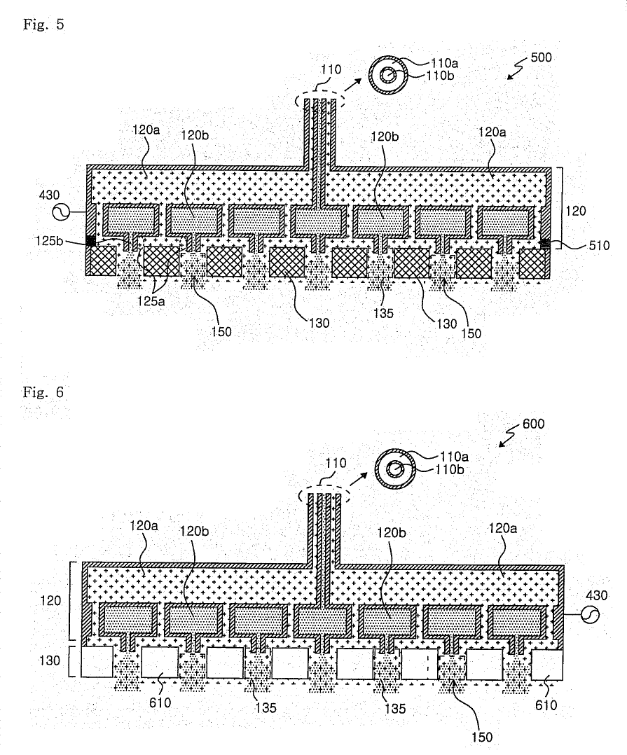

FIG. 3 illustrates an ALD apparatus according to an embodiment of the present invention.

An ALD apparatus 300 shown in FIG. 3 employs the gas separation type showerhead 100 shown In FIG. 1. The ALD apparatus 300 includes a first precursor source 310, a second precursor source 320, a purge gas source 330, and an exhaust unit 340.

The first precursor source 310 stores the first precursor A. The first precursor source 310 is connected to the outer supply tube 110a of the gas supply module 110 of the gas separation type showerhead 100.

The second precursor source 320 stores the second precursor B. The second precursor source 320 is connected to the inner supply tube 110b of the gas supply module 110 of the gas separation type showerhead 100.

The purge gas source 330 stores a purge gas. The purge gas source 330 is connected to the outer and inner supply tubes 110a and 110b of the gas supply module 110 of the gas separation type showerhead 100. The purge gas may be a nitrogen gas (N₂).

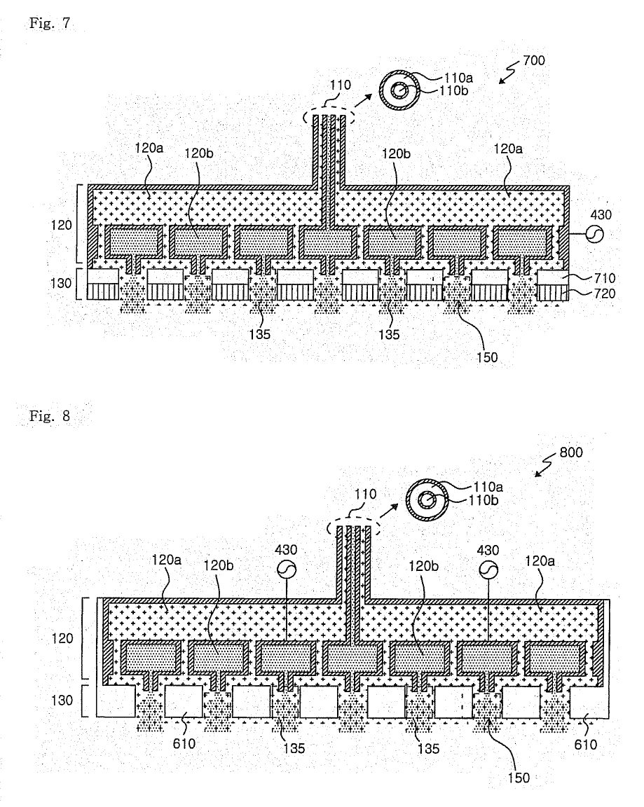

The first precursor source 310, the second precursor source 320, and the purge gas source 330 are connected to a plurality of valves v/v 1 to v/v 4 which can control opening and shutting of apertures through which a gas flows. As shown in FIG. 4, there are provided a plurality of mass flow controllers (MFC) which can control a flow rate of each gas.

After the first or second precursor A or B is injected through the gas injection module 130 of the gas separation type showerhead 100, the purge gas is supplied to at least one of the outer and inner supply tubes 110a and 110b of the gas supply module 110 of the gas separation type showerhead 100 and injected into a reaction chamber 301 through the plurality of holes 135 included in the gas injection module 130.

After the first precursor A is injected, in order to purge paths of the first precursor A such as the outer supply tube 110a, the first dispersion region 120a, and the like, the purge gas may be supplied to the outer supply tube 110a or the outer and inner supply tubes 110a and 110b. Similarly, after the second precursor B is injected, the purge gas may be supplied to the inner supply tube 110b or the outer and inner supply tubes 110a and 110b of the gas supply module 110 of the gas separation type showerhead 100.

Since the first and second precursors A and B are alternately supplied to the gas supply module 110 of the gas separation type showerhead 100, when the first precursor A is supplied to the outer supply tube 110a and injected into the reaction chamber 301, It is possible for the first precursor to flow backward to the plurality of vents 125. Accordingly, backflow of the first precursor A can be prevented by supplying the purge gas to the inner supply tube 110b, when the first precursor A is supplied to the outer supply tube 110a. Similarly, backflow of the second precursor B can be prevented by supplying the purge gas to the outer supply tube 110a, when the second precursor B is supplied to the inner supply tube 110b. At this time, since the supplied purge gas is used to prevent backflow, the purge gas may have less flow rate than the first or second precursor A or B.

The exhaust unit 340 exhausts remaining materials of the reaction chamber 301, after the reaction chamber 301 is purged by the purge gas. For this, the exhaust unit 340 is provided with a pump.

The exhaust unit 340 may be directly connected to the first and second precursor sources 310 and 320. In this case, when the first precursor is injected, the second precursor is diverted through the exhaust unit 340 without passing through the gas separation type showerhead 100. When the second precursor is injected, the first precursor is diverted through the exhaust unit 340 without passing through the gas separation type showerhead 100.

FIG. 4 illustrates an ALD apparatus according to another embodiment of the present invention.

In an ALD apparatus 400 shown in FIG. 4, a first precursor A may be bubbled together with a carrier gas supplied from a carrier gas source 410 and supplied to the gas separation type showerhead 100. A second precursor B together with an inert gas supplied from an inert gas source 420 may be supplied to the gas separation type showerhead 100.

In addition, the ALD apparatus 400 shown in FIG. 4 is further provided with a power source 430 for supplying power for ionization.

In a general ALD process, in order to maintain original shapes of the first and second precursors A and B, non-ionized first and second precursors A and B are injected into the reaction chamber 301. However, one gas of the first and second precursors A and B needs to be ionized and injected, or the first and second precursors A and B need to be ionized and injected, in some cases.

Accordingly, when a power source 430 directly applies power for ionization to the gas separation module 120 of the gas separation type showerhead 100, a precursor of the first and second precursors A and B, which needs to be ionized, may be ionized in the gas separation type showerhead 100 and supplied to the inside of the reaction chamber 301.

The power for ionization may use one of direct current (DC) power, radio frequency (RF) power, and microwave power.

Particularly, when the power for ionization is the RF power, the power may have a single frequency, or two or more frequencies. For example, when the power source 430 applies the power for ionization to the gas separation module 120, the power may be a power having a single frequency of 13.56 MHz or a power having frequencies 13.56 MHz and 370 KHz.

The power source 430 may apply the power for ionization to a single location. However, as the size of the showerhead increases, the power source 430 may apply the power for ionization to a plurality of locations of the gas separation module 120.

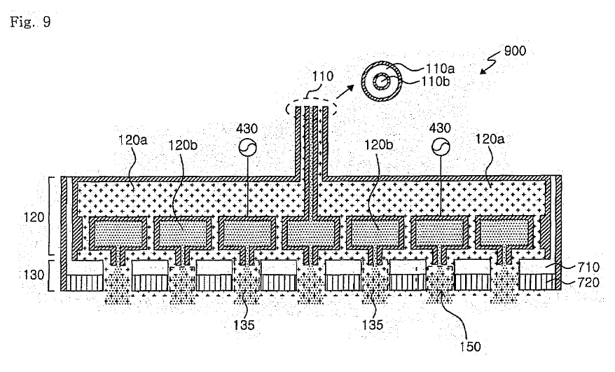

FIG. 5 illustrates another example of a gas separation type showerhead used for the present invention.

In a gas separation type showerhead 500 shown in FIG. 5, the power source 430 applies the power for ionization to the gas separation module 120.

When there is an insulator ring 510 between the gas separation module 120 and the gas injection module 130, the gas injection module 130 is electrically insulated from the gas separation module 120. Accordingly, the influence of the power is blocked between the gas separation module 120 and the gas injection module 130. Accordingly, the power applied to the gas separation module 120 by the power source 430 does not influence the gas injection module 130.

FIGS. 6 and 7 illustrate examples of a gas separation type showerhead used for the present invention.

The gas injection module 130 of the gas separation type showerhead 600 shown in FIG. 6 is made of an insulator 610.

When the gas separation module 130 is made of the insulator 610, since an influence of plasma is blocked by the insulator, the influence of plasma on a semiconductor substrate and other devices in the reaction chamber 301 can be minimized.

The insulator 610 may be a ceramic such as aluminum oxide (Al₂O₃) and aluminum nitride (AIN), a polymer such as Teflon, or a compound of a ceramic and a polymer.

The gas injection module 130 of the gas separation type showerhead 700 shown in FIG. 7 is constructed by combining an upper plate 710 with a lower plate 720.

The upper plate 710 is made of an insulator so as to block plasma. The lower plate 720 is made of a conductor such as aluminum (Al) so as to serve as a ground with respect to the power for ionization.

In the gas separation type showerheads 600 and 700 shown in FIGS. 6 and 7, since the gas injection module 130 includes an insulator, the insulator can effectively block the influence of the power for ionization without inserting a separate insulator ring 510 (FIG. 5), when the power source 430 applies the power for ionization to the gas separation module 120. In the gas separation type showerheads 600 and 700 shown in FIGS. 6 and 7, since the insulators 610 and 710 are located at lower side of the showerhead, the influence of plasma on an injection surface of the showerhead is extremely reduced. Accordingly, it is possible to prevent a damage of the semiconductor located close to the showerhead.

In the gas separation type showerhead 800 shown in FIG. 8, the insulator shown in FIG. 6 extends to the sides of the showerhead. In the gas separation type showerhead 900 shown in FIG. 9, the upper and lower plates 710 and 720 extend to the sides of the showerhead. The gas separation type showerheads 800 and 900 are structures in which the areas of the insulators 610 and 710 are expanded. The influence of plasma in the reaction chamber 301 may be furthermore reduced.

An example of an ALD process in which plasma is applied when the second precursor is supplied by using the ALD apparatus that employs the gas separation type showerhead according to an embodiment of the present invention will be described in the following.

First, the first precursor source 310 injects the first precursor A into the reaction chamber 301 through the gas separation type showerhead 100 so as to adsorb the first precursor on a surface of the semiconductor substrate. Then, the purge gas source 330 injects the purge gas into the reaction chamber 301 through the gas separation type showerhead 100 so as to purge the inside of the reaction chamber 301.

Then, the power source 430 applies the RF power for ionization to the gas separation module 120 of the gas separation type showerhead 100. The second precursor source 320 injects an ionized second precursor B into the reaction chamber 301 through the gas separation type showerhead 100 so as to react the second precursor B with the first precursor A.

Then, an application of the power is stopped, and the purge gas source 330 injects the purge gas into the reaction chamber through the gas separation type showerhead 100 so as to purge the inside of the reaction chamber 301.

A desired ALD film can be formed by repeating the aforementioned processes.

At this time, when the first precursor A is supplied, backflow of the first precursor A can be prevented by allowing a little amount of the purge gas to flow through the inner supply tube 110b. When the second precursor B is supplied, backflow of the second precursor B can be prevented by allowing a little amount of the purge gas to flow through the outer supply tube 110a.

As described above, in the ALD apparatus according to an embodiment of the present invention, precursors do not react with each other. It is possible to suppress production of by-products in a showerhead and maintain uniformity of a gas flow in the reaction chamber by using the showerhead in which the precursors are finally injected through the same injection holes.

In addition, in the ALD apparatus according to an embodiment of the present invention, plasma is generated by directly applying the power for ionization to the gas separation module of the gas separation type showerhead. It is possible to minimize loss of the plasma and the influence of the generation of the plasma on the semiconductor substrate or devices in the reaction chamber by including an insulator at the lower sides of the gas separation type showerhead and supplying the precursors through the least path.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An ALD (atomic layer deposition) apparatus that employs a gas separation type showerhead which includes a gas supply module having an outer supply tube through which a first precursor is supplied and an inner supply tube through which a second precursor is supplied, a gas separation module having a first dispersion region connected to the outer supply tube and a second dispersion region connected to the inner supply tube, and a gas injection module having a plurality of common holes through which the first and second precursors are alternately injected into a reaction chamber, the ALD apparatus comprising:
a first precursor source storing the first precursor, which is connected to the outer supply tube;
a second precursor source storing the second precursor, which is connected to the inner supply tube;
a purge gas source storing a purge gas, which is connected to the outer and inner supply tubes;
a power source which applies power for ionization to the gas separation module; and
an exhaust unit which exhausts remaining materials of the reaction chamber.

2. The ALD apparatus of claim 1, wherein the gas separation type showerhead further includes an insulator ring for electrically insulating the gas injection module from the gas separation module.

3. The ALD apparatus of claim 1, wherein the gas injection module is made of an insulator.

4. The ALD apparatus of claim 1,
wherein the gas injection module is constructed by combining un upper plate with a lower plate, and
wherein the upper plate is made of an insulator, and the lower plate is made of a conductor for grounding.

5. The ALD apparatus of claim 1, wherein the purge gas is supplied at least one of the outer and inner supply tubes and injected into the reaction chamber through the plurality of common holes, after the first or second precursor is injected.

6. The ALD apparatus of claim 1,
wherein the purge gas is supplied to the inner supply tube, when the first precursor is supplied to the outer supply tube, and
wherein the purge gas is supplied to the outer supply tube, when the second precursor is supplied to the inner supply tube.

7. The ALD apparatus of claim 1,
wherein the exhaust unit is directly connected to the first and second precursor sources, respectively,
wherein the second precursor is diverted through the exhaust unit without passing through the gas separation type showerhead, when the first precursor is injected, and
wherein the first precursor is diverted through the exhaust unit without passing through the gas separation type showerhead, when the second precursor is injected.

8. The ALD apparatus of claim 1, wherein the gas separation module comprises:
a first dispersion region which is connected to the outer supply tube and constructed with one region, the region in which the first precursor is dispersed;
a second dispersion region which is located under the first dispersion region, which is connected to the inner supply tube and divided into a plurality of regions, the plurality of regions in which the second precursor is dispersed; and
a plurality of vents which are located at lower parts of the plurality of regions of the second dispersion region, the plurality of vents through which the second precursor is vented.

9. The ALD apparatus of claim 8, wherein the plurality of regions of the second dispersion region include gas distribution plates for uniformly dispersing the second precursor.

10. The ALD apparatus of claim 8, wherein the first precursor is vented to spaces surrounding the plurality of vents from the first dispersion region through outer spaces of the plurality of regions of the second dispersion region.
